(19) United States
(12) Patent Application Publication
(10) Pub. No.: US 2012/0188151 A1
(43) Pub. Date: Jul. 26, 2012

(54) LIQUID CRYSTAL DISPLAY DEVICE AND MANUFACTURING METHOD THEREOF

(75) Inventor: Hyun-Uk OH, Asan-si (KR)

(73) Assignee: SAMSUNG MOBILE DISPLAY CO., LTD., Yongin-city (KR)

(21) Appl. No.: 13/168,696

(22) Filed: Jun. 24, 2011

(30) Foreign Application Priority Data
Jan. 21, 2011 (KR) 10-2011-0006455

(51) Int. Cl. G09G 3/36; H01L 33/50

(52) U.S. Cl. 345/88; 345/87; 438/29; 257/E33.06

(57) ABSTRACT

Provided are a liquid crystal display device and a method of manufacturing the same. The liquid crystal display device includes opposing first and second substrates, the first and second substrates including a display area for displaying an image and a non-display area surrounding the display area, a first black matrix disposed in the non-display area on the first substrate, a first insulation layer disposed on the second substrate, first and second alignment layers disposed on at least one of the first black matrix and the first insulation layer, the first and second alignment layers extending from the display area toward the non-display area, and a seal pattern disposed on the first insulation layer in the non-display area. The seal pattern is spaced apart from at least one of the first and second alignment layers.

### CROSS-REFERENCE TO RELATED APPLICATION

This application claims priority from and the benefit of Korean Patent Application No. 10-2011-0006455, filed on Jan. 21, 2011, which is hereby incorporated by reference for all purposes as if fully set forth herein.

### BACKGROUND OF THE INVENTION

1. Field of the Invention

Exemplary embodiments of the present invention relate to a liquid crystal display device and a method of manufacturing the same.

2. Discussion of the Background

Liquid crystal display devices use the optical anisotropic characteristics of liquid crystals to display an image. In such a liquid crystal display device, light is radiated on liquid crystals that have polarization properties. When an electric field is applied thereto, the amount of transmitted light is controlled by controlling the orientations of liquid crystals using the electric field. Thus, an image may be displayed using this principle.

The liquid crystal display device includes a thin film transistor substrate, on which a thin film transistor and a pixel electrode are provided, a color filter substrate, on which a color filter and a common electrode are provided, and a liquid crystal layer that is disposed between the thin film transistor substrate and the color filter substrate.

### SUMMARY OF THE INVENTION

The present disclosure provides a liquid crystal display device having a structure that prevents the separation of upper and lower substrates, to reduce defects in the application of a black matrix, and a method of manufacturing the same.

Additional features of the invention will be set forth in the description which follows, and in part will be apparent from the description, or may be learned by practice of the invention.

Embodiments of the inventive concept provide liquid crystal display devices including: first and second substrates facing each other, the first and second substrates including a display area for displaying an image and a non-display area surrounding the display area; a first black matrix disposed in the non-display area of the first substrate; a first insulation layer disposed on the second substrate; first and second alignment layers disposed on at least one of the first black matrix and the first insulation layer, the first and second alignment layers extending from the display area toward the non-display area; and a seal pattern disposed on the first insulation layer of the non-display area, the seal pattern being spaced apart from at least one of the first and second alignment layers and bonding the first substrate to the second substrate so that the first black matrix faces the first insulation layer.

In other embodiments of the inventive concept, methods of manufacturing a liquid crystal display device include: preparing a second substrate including a thin film transistor formed in a display area, a first insulation layer formed on the thin film transistor, and a pixel electrode formed on the first insulation layer and connected to a drain electrode of the thin film transistor; forming a second photoresist pattern on the first insulation layer in a non-display area surrounding the display area; forming a second alignment layer on the second photoresist pattern, the pixel electrode, and the first insulation layer; removing the second photoresist pattern and the second alignment layer formed on a top surface and sidewall of the second photoresist pattern through a lift-off process; and forming a seal pattern spaced apart from the second alignment layer remaining on the first insulation layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a sectional view of a liquid crystal display device according to an embodiment of the inventive concept.

FIGS. 2A, 2B, 2C, 2D, 2E, 2F, 2G, 2H, 2I, 2J, 2K, 2L, 2M, and 2N are sectional views illustrating a method of manufacturing a liquid crystal display device according to an embodiment of the inventive concept.

### DETAILED DESCRIPTION OF PREFERRED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. Also, in the figures, the dimensions of layers and regions are exaggerated for clarity of illustration. Also, though terms like a first, a second, and a third are used to describe various regions and layers in various embodiments of the present invention, the regions and the layers are not limited to these terms. These terms are used only to discriminate one region or layer from another region or layer. An embodiment described and exemplified herein includes a complementary embodiment thereof. Like reference numerals refer to like elements throughout.

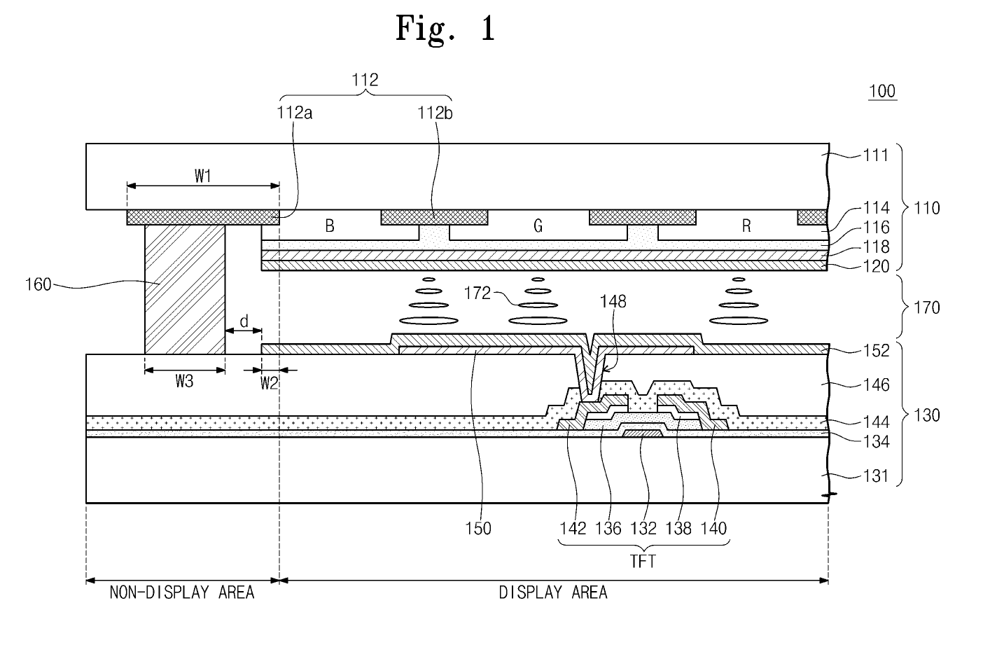

FIG. 1 is a sectional view of a liquid crystal display device 100, according to an embodiment of the present inventive concept. Referring to FIG. 1, the liquid crystal display device 100 includes a color filter substrate 110, an opposing thin film transistor substrate 130, and a liquid crystal layer 170 disposed between the color filter substrate 110 and the thin film transistor substrate 130. The display device 100 is divided into a display area where an image is formed and a non-display area surrounding the display area.

The color filter substrate 110 includes a first substrate 111. The first substrate 111 may be formed of a transparent material. For example, the first substrate 111 may be formed of glass or plastic.

Black matrixes (BMs) 112 are disposed on the first substrate 111. The black matrixes 112 include a first black matrix 112a and a second black matrix 112b, which are separated from one another using a patterning process. The first black matrix 112a is disposed in the non-display area. The second black matrix 112b is disposed in the display area.

The first black matrix 112a may have a closed loop shape and may surround the display area, to prevent light from leaking therefrom. The width W1 of the first black matrix 112a may be set according to the width of a seal pattern 160. The width W1 of the first black matrix 112a may be about 0.3 mm to about 1.2 mm, as measured from an edge of the display area toward an outer edge of the non-display area. The first black matrix 112a may be a slim or ultra-slim black matrix.

The second black matrix 112b may cover (face) a thin film transistor TFT of the thin film transistor substrate 130, a gate line (not shown), and a data line (not shown), to prevent light leakage. Also, the second black matrix 112b may have a plurality of openings. Color filter layers 114 may be disposed in the openings to prevent colors from being mixed between the color filter layers 114. In other words, the second black matrix may dispose between adjacent color filter layers 114.

Each of the black matrixes 112 may be formed of a metal. For example, the black matrixes 112 may be formed of Cr, CrOx, or a dual layer thereof.

The color filter layers 114 have a red color R, a green color G, and a blue color B, due to transmitting only light having a specific wavelength. The color filter layers 114 may be disposed between/within the black matrixes 112. The color filter layers 114 may contain an acryl resin and a pigment. The color filter layers 114 may be classified as a red color filter layer, a green color filter layer, and a blue color filter layer, according to the type of pigment included therein.

An overcoat layer 116 may be additionally disposed on the second black matrix 112b and the color filter layers 114. The overcoat layer 116 may protect and planarize the color filter layers 114. In addition, the overcoat layer 116 may improve adhesion with a common electrode 118. For example, the overcoat layer 116 may be formed of an acryl-based resin.

The common electrode 118 may be disposed on the overcoat layer 116. The common electrode 118 may be formed of a transparent conductive material. For example, the common electrode 118 may be formed of indium tin oxide (ITO) or indium zinc oxide (IZO). A first alignment layer 120 may be disposed on the common electrode 118, to pre-tilt liquid crystals 172. The first alignment layer 120 may extend to the first black matrix 112a, at an edge of the non-display area. The first alignment layer 120 may extend into the non-display area and onto the first black matrix 112a, by a second width (distance) W2 of about 1 μm to about 99 μm.

The first alignment layer 120 may be formed of a resin. For example, the first alignment layer 120 may be formed of a polyimide having an affinity with the liquid crystals 172.

A spacer (not shown) may be additionally disposed on the color filter substrate 110, to maintain a certain cell gap between the color filter substrate 110 and the thin film transistor 130. The spacer may be formed of a resin of organic polymer materials.

The thin film transistor substrate 130 includes a second substrate 131. The second substrate 131 may be formed of a transparent material. For example, the second substrate 131 may be formed of glass or plastic.

A thin film transistor TFT including a gate electrode 132, a semiconductor layer 136, an ohmic contact layer 138, a source electrode 140, and a drain electrode 142 may be disposed on the second substrate 131 and in the display area. The TFT is a switching device for selectively applying a signal to the liquid crystals 172.

The gate electrode 132 may be formed of a conductive material, such as a metal. For example, the gate electrode 132 may be formed of at least one of Al, AlNd, W, Cr, Ti, and Mo.

A gate insulation layer 134 may be disposed between the gate electrode 132 and the semiconductor layer 136. The gate insulation layer 134 extends into the non-display area. The gate insulation layer 134 may be formed of silicon oxide (SiO₂).

The semiconductor layer 136 may be disposed on the gate insulation layer 134 facing the gate electrode 132. The semiconductor layer 136 may be formed of an intrinsic amorphous silicon (a-Si:H). The ohmic contact layer 138 may be disposed on the semiconductor layer 136. The ohmic contact layer 138 may be formed of an amorphous silicon (n+ a-Si:H) doped with impurities. A portion of the semiconductor layer 136 may be exposed through the ohmic contact layer 138.

The source electrode 140 and the drain electrode 142 may be spaced apart from each other on the ohmic contact layer 138. The source electrode 140 and the drain electrode 142 may be formed of at least one of Mo, Ti, W, MoW, Cr, Ni, Al, and AlNd. A channel electrically connecting the source electrode 140 to the drain electrode 142 is formed in a portion of the semiconductor layer 136 between the source electrode 140 and the drain electrode 142. Thus, when a high level voltage is applied to the gate electrode 132, and a data voltage is applied to the source electrode 140, the data voltage applied to the source electrode 140 is supplied to the drain electrode 142, via the semiconductor layer 136, by the high level voltage applied to the gate electrode 132.

Although not shown, a gate line connected to the gate electrode 132 is disposed in a first direction, and a data line connected to the source electrode 140 is disposed in a second direction crossing the first direction. An area in which the gate line crosses the data line is referred to as a pixel area.

A first insulation layer 144 and a second insulation layer 146 are successively stacked on the TFT. The first insulation layer 144 protects the TFT and prevents the second insulation layer 146 from being unfilled. The first insulation layer 144 may extend on the gate insulation layer 134 into the non-display area. The first insulation layer 144 may be formed of silicon oxide (SiO₂), silicon nitride (SiNₓ), or a duel layer thereof.

The second insulation layer 146 may be formed of an organic material, to reduce a parasitic capacitance between the gate line (not shown) and a pixel electrode 150. For example, the second insulation layer 146 may be formed of a material having low dielectric constant, such as an acryl resin or benzocyclobutene (BCB). The second insulation layer 146 may extend on the first insulation layer 144 into the non-display area.

A contact hole 148 for exposing a portion of the drain electrode 142 may be formed in the second insulation layer 146 and the first insulation layer 144, in the display area. The pixel electrode 150 is electrically connected to the drain electrode 142 through the contact hole 148. The pixel electrode 150 may be disposed on the second insulation layer 146 in the display area. The pixel electrode 150 may face the color filter layers 114. The pixel electrode 150 may be formed of a transparent conductive material. For example, the pixel electrode 150 may be formed of indium tin oxide (ITO).

A second alignment layer 152 for pre-tilting the liquid crystals 172 may be disposed on the pixel electrode 150 and the second insulation layer 146. The second alignment layer 152 may extend on the second insulation layer 146 into the non-display area. The second alignment layer 152 may extend into the non-display area by the second width (distance) W2.

The second alignment layer 152 may be formed of a resin. For example, the second alignment layer 152 may be formed of a polyimide having an affinity with the liquid crystals 172.

The color filter substrate 110 and the thin film transistor substrate 130 are bonded the seal pattern 160 disposed in the non-display area. The seal pattern 160 is spaced apart from the second alignment layer 152 and is disposed on the second insulation layer 146. The seal pattern 160 may be attached to opposing portions of the second insulation layer 146 and the first black matrix 112a.

For example, the seal pattern 160 may have a third width W3 of about 0.2 mm to about 0.7 mm. For example, the seal pattern 160 may be spaced apart from at least one of the first alignment layer 120 and the second alignment layer 152, by a distance “d” of about 0.1 mm to about 0.5 mm. The seal pattern 160 may be formed of a sealant. For example, the sealant may be a photo-curable resin or a thermally-curable resin.

The liquid crystal layer 170 is disposed between the color filter substrate 110 and the thin film transistor substrate 130. The liquid crystal layer 170 may include the liquid crystals 172 having optical anisotropic characteristics.

In the liquid crystal display device 100, a voltage is applied to the pixel electrode 150 through the drain electrode 142. Then, the voltage is applied to the common electrode 118 to operate liquid crystal cells, thereby displaying an image.

Typically, when a seal pattern overlaps with/contacts a first and/or second alignment layer, due to a processing error margin of the first and/or second alignment layers, the connection between a color filter substrate and a thin film transistor substrate may be weakened. As a result, the color filter substrate and the thin film transistor substrate may be separated from each other, resulting in product defects.

However, in the liquid crystal display device 100, the size of the portions of the first and/or second alignment layers 120 and 152 disposed in the non-display area are reduced, to separate the seal pattern 160 from the first and/or second alignment layers 120 and 152. Therefore, the upper and lower substrates 110 and 130 are well adhered, thereby improving product quality.

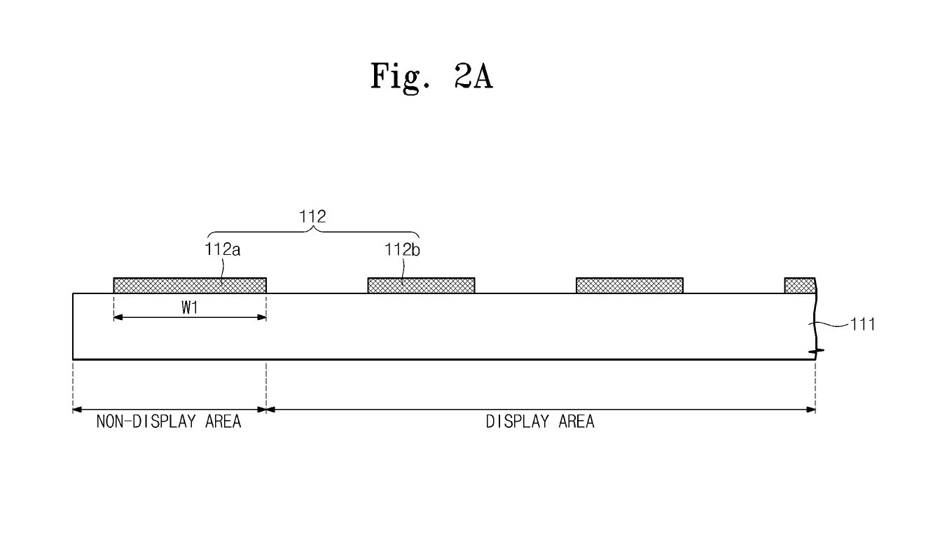

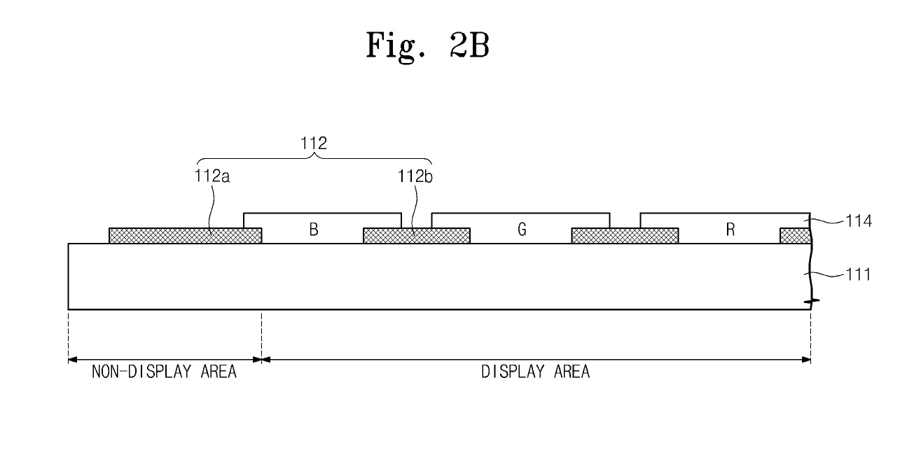

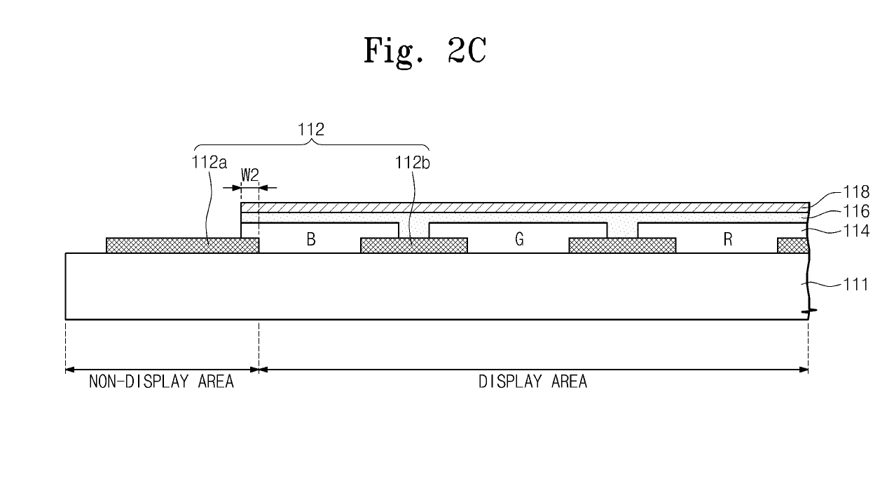

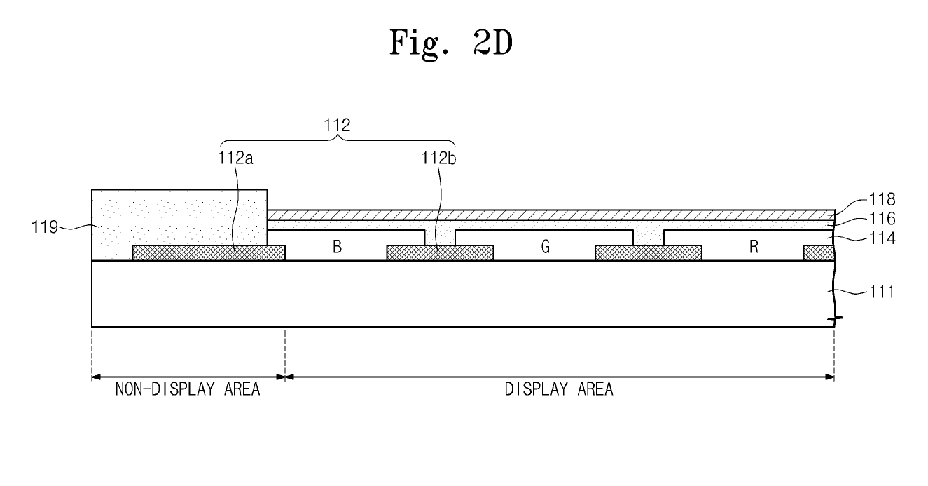

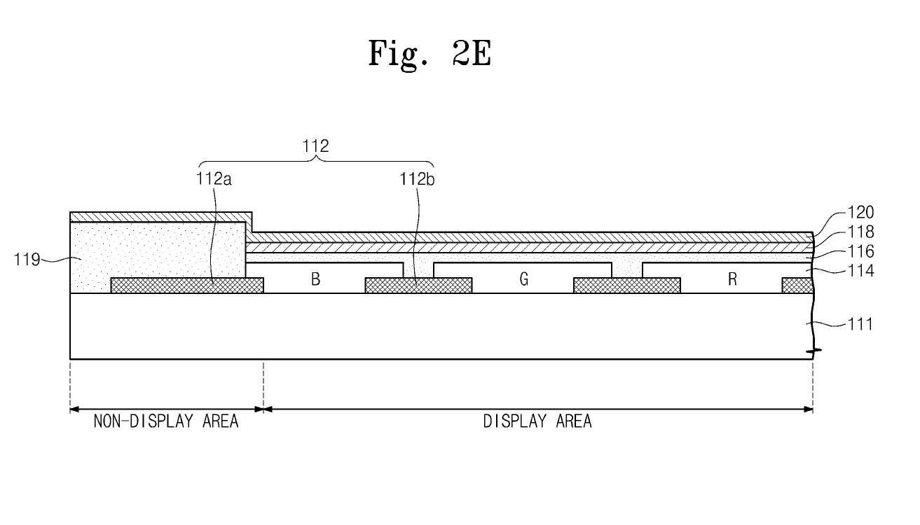

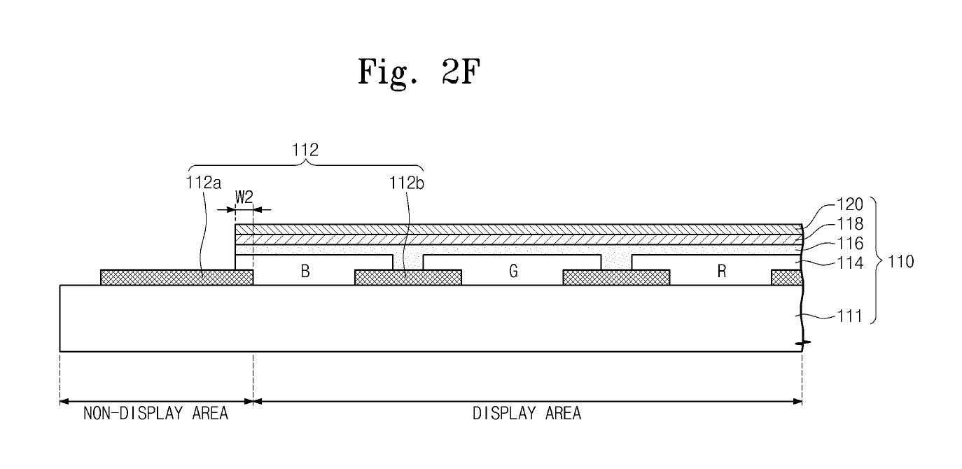

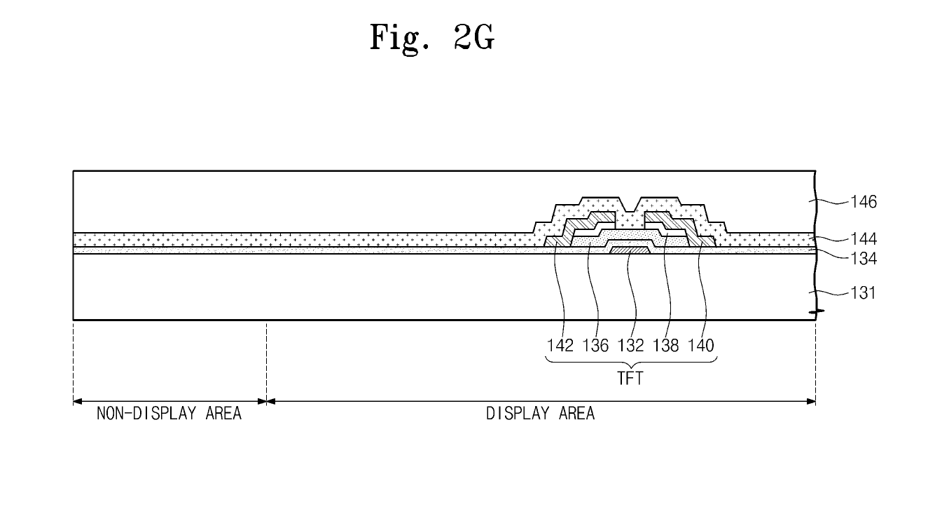

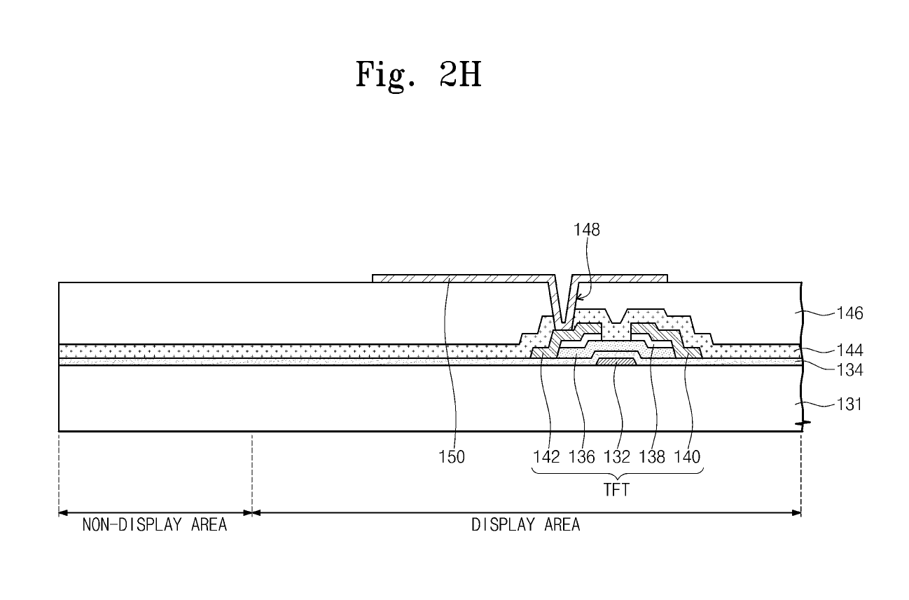

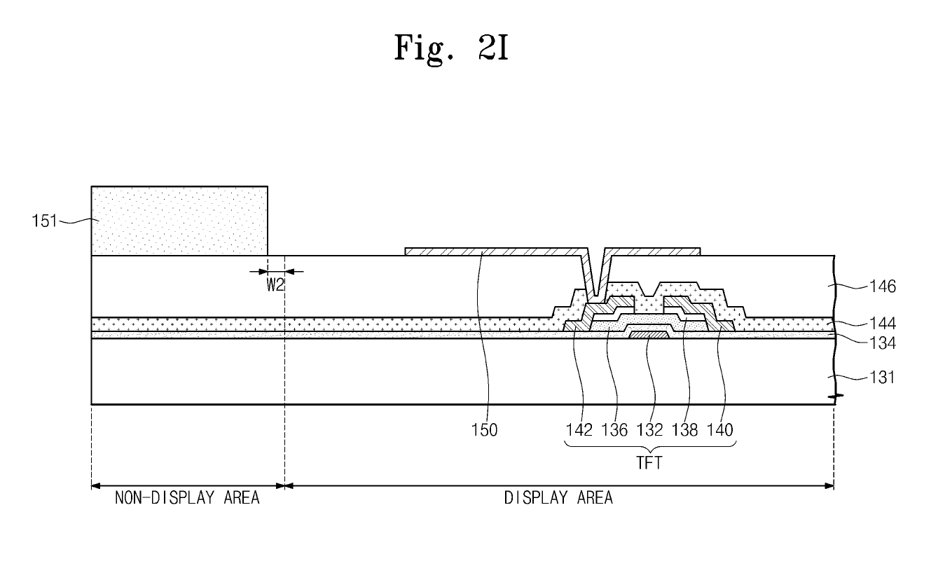

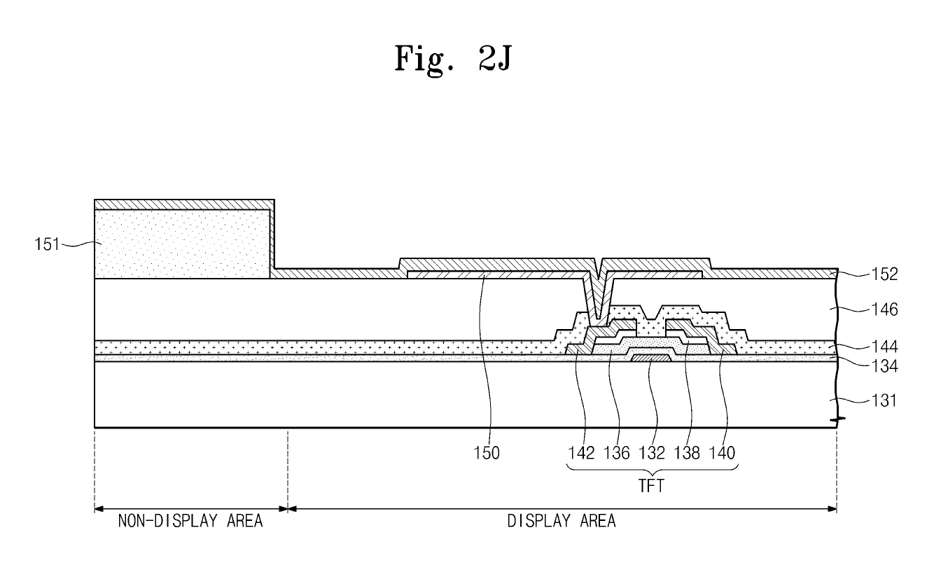

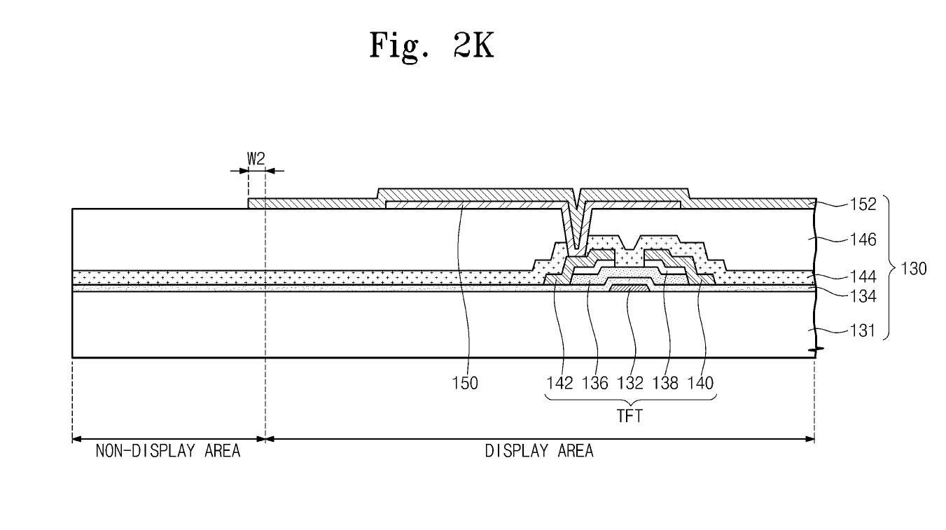

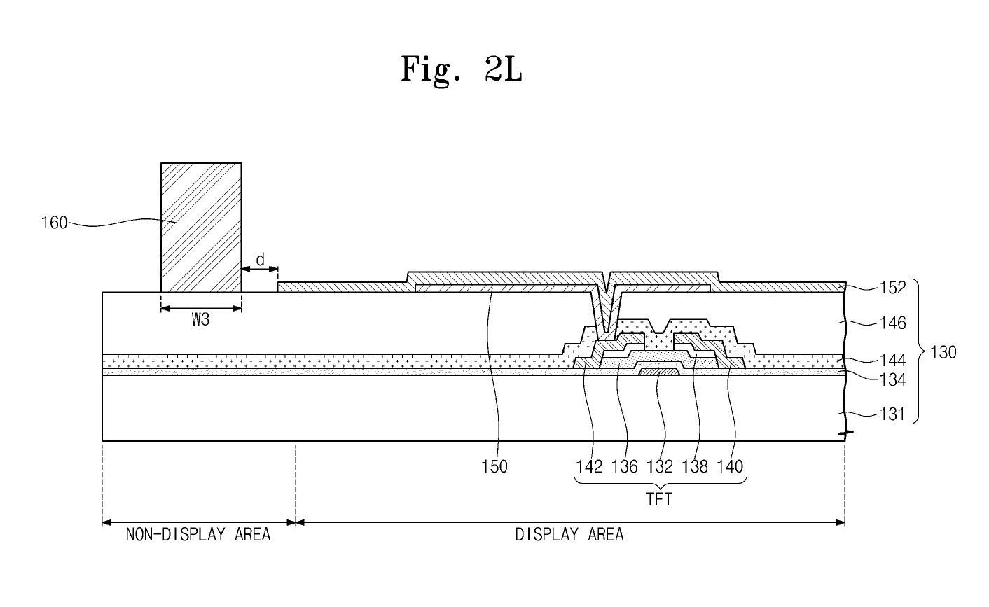

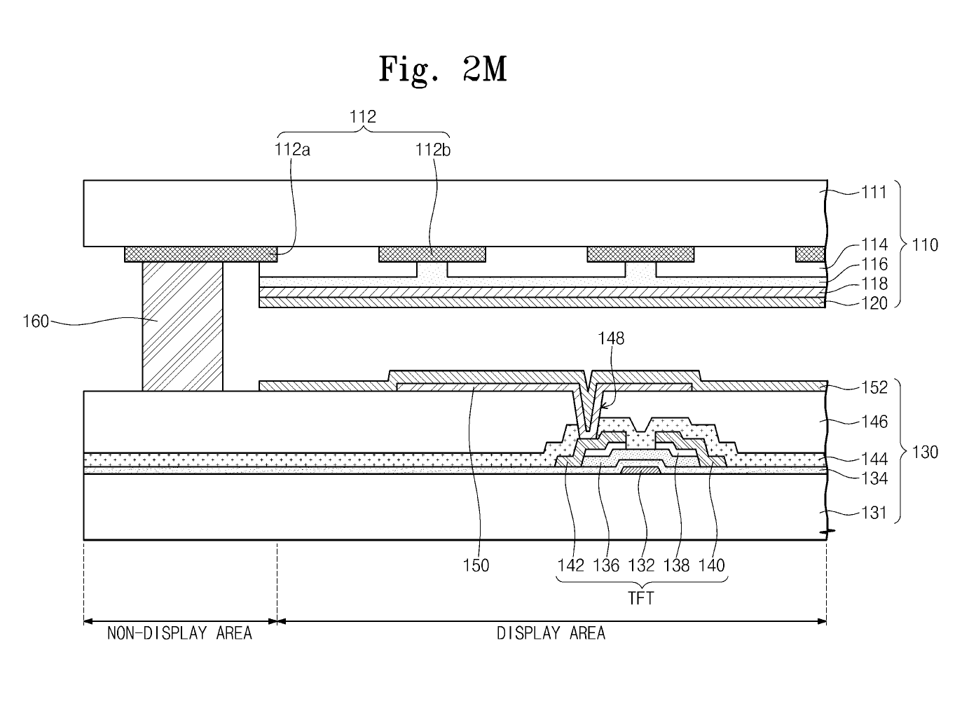

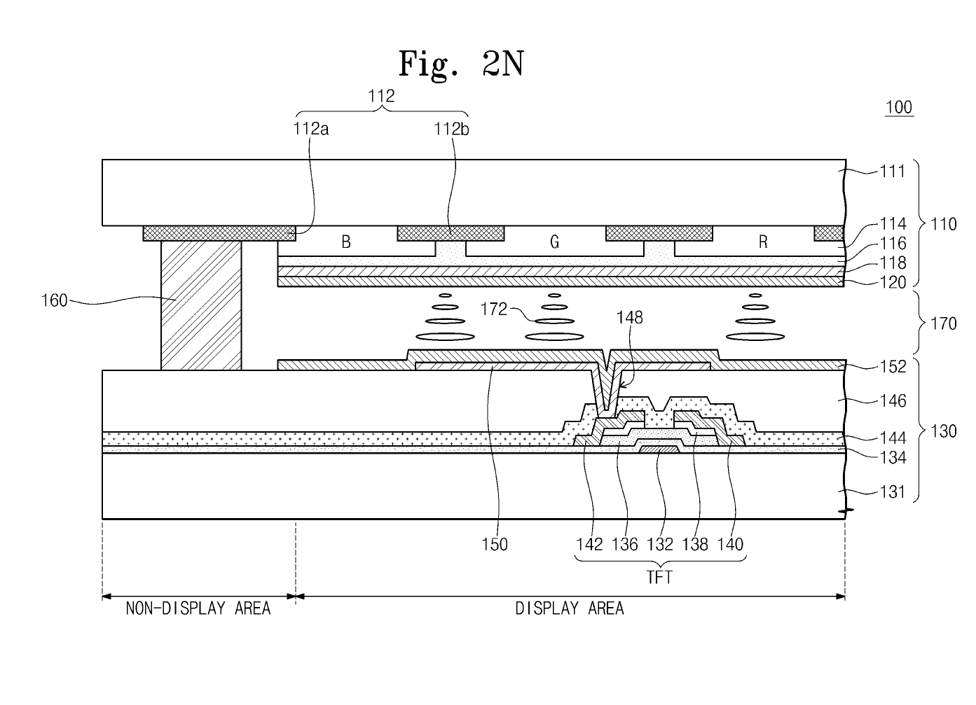

FIGS. 2A to 2N are sectional views illustrating a method of manufacturing the liquid crystal display device 100, according to an exemplary embodiment of the present inventive concept. Referring to FIG. 2A, the first substrate 111 is prepared. The first black matrix 112a is disposed on the first substrate 111, in the non-display area.

The second black matrix 112b is formed on the first substrate 111 in the display area. The second black matrix 112b is separated from the first black matrix 112a.

A metal layer may be formed on the first substrate 111, and then, the metal layer may be patterned using a mask, to form the black matrixes 112. The patterning process may be a typical photolithography process. Thus, a description thereof will be omitted.

Referring to FIG. 2B, the color filter layers 114 are formed on the first substrate 111, between the black matrixes 112. In particular, a film may be coated on the first substrate 111 using spin coating. Then, the film may be patterned using a mask, or may be directly patterned using laser induced thermal imaging (LITI), to form the color filter layers 114. The color filter layers 114 may extend onto edges of the black matrixes 112.

Referring to FIG. 2C, the overcoat layer 116 is formed on the color filter layers 114 and the exposed second matrix 112b. The common electrode 118 is then formed on the overcoat layer 116. For example, the overcoat layer 116 may be formed by applying an acryl-based resin. According to some aspects, the overcoat layer 116 may be omitted.

In particular, a resin layer may be formed using spinning coating, and then, a sputtering process may be performed on the resin layer, to form a transparent conductive layer. Then, the transparent conductive layer and the resin layer may be sequentially patterned using a mask, to form the overcoat layer 116 and the common electrode 118.

Referring to FIG. 2D, the first photoresist pattern 119 is formed on the exposed first black matrix 112a and the exposed first substrate 111, in the non-display area. In particular, a photoresist material may be coated on the common electrode 118, the exposed first black matrix 112a, and the exposed the first substrate 111, to form a first photoresist layer (not shown). Then, the first photoresist layer may be patterned using a mask, to form the first photoresist pattern 119. The first photoresist pattern 119 may have a thickness at least about four times the thickness of the subsequently formed first alignment layer 120 (FIG. 2F).

Referring to FIG. 2E, the first alignment layer 120 is formed on the first photoresist pattern 190 and the common electrode 118. The first alignment layer 120 may be formed by coating polyimide using roller coating, spin coating, or dipping. For example, the first alignment layer 120 may have a thickness of about 500 Å. The first alignment layer 120 may have a thinner thickness on a sidewall of the first photoresist pattern 119 than on a top surface of the first photoresist pattern 119 and the common electrode 118.

Referring to FIG. 2F, the first photoresist pattern 119 is removed through a lift-off process. The lift-off process may be performed using an etchant having a higher selectivity with respect to the first photoresist pattern 119 than with the first alignment layer 120. For example, a sulfuric acid solution (H₂SO₄) having a temperature of about 150° C. to about 180° C. may be used.

During the etching process, the relatively thin portion of the first alignment layer disposed on the sidewall of the first photoresist pattern 119 may be etched away, so that an upper portion of the sidewall of the first photoresist pattern 119 is exposed. Then, the exposed first photoresist pattern 119 may be quickly etched. Thus, the portion of the first alignment layer 120 formed on the first photoresist pattern 119 of FIG. 2E may be separated. As such, the first alignment layer 120 may remain on only the common electrode 118. The lift off process allows a portion of the first alignment layer 120 having the width W2 to remain in the non-display area.

A spacer (not shown) may be formed on the first substrate 111 to maintain a certain cell gap between the first substrate 111 and a lower substrate. An organic polymer material may be deposited and patterned to form the spacer. Also, the spacer may be omitted. Therefore, a color filter substrate 110 that is an upper substrate may be formed.

Referring to FIG. 2G, the second substrate 131 is prepared. The thin film transistor TFT including the gate electrode 132, the semiconductor layer 136, the ohmic contact layer 138, the source electrode 140, and the drain electrode 142 are formed in the display area and on the second substrate 131. A conductive metal may be deposited on the second substrate 131 using sputtering or evaporation, to form a conductive metal layer. Then, the conductive metal layer may be patterned using a mask to form the gate electrode 132. Although not shown, a gate line or a data line may be formed when the gate electrode 132.

The gate insulation layer 134 is formed on the gate electrode 132 and the exposed second substrate 131. Silicon oxide (SiO₂) may be deposited on the gate electrode 132 through chemical vapor deposition (CVD), to form the gate insulation layer 134.

An intrinsic amorphous silicon layer and an amorphous silicon layer, in which n-type or p-type impurities are doped, may be sequentially formed on the gate insulation layer 132 through CVD. Then, the intrinsic amorphous silicon layer and the amorphous silicon layer may be patterned using a mask, to form the semiconductor layer 136 and the ohmic contact layer 138. The ohmic contact layer 138 may be omitted, according to some aspects.

A conductive metal may be deposited on the ohmic contact layer 138 and the gate insulation layer 134 using sputtering or evaporation, to form a conductive metal layer. Then, the conductive metal layer may be patterned using a mask, to form the source electrode 140 and the drain electrode 142 on the ohmic contact layer 138. Here, an area in which the semiconductor layer 136 is exposed between the source electrode 140 and the drain electrode 142 may be referred to as a channel.

The first insulation layer 144 and the second insulation layer 146 are sequentially formed on the thin film transistor TFT and the gate insulation layer 134. In particular, a silicon oxide layer (SiO₂), a silicon nitride layer (SiNx), or a dual layer thereof may be formed on the thin film transistor TFT and the gate insulation layer 134, using CVD. An organic material, such as an acryl resin or a BCB, may be coated through spin coating, to form the second insulation layer 146. Thus, the first insulation layer 144 and the second insulation layer 146 may be formed on the entire surface of the gate insulation layer 134.

Referring to FIG. 2H, a patterning process may be performed on the first insulation layer 144 and the second insulation layer 146 using a mask, to form a contact hole 148 exposing a portion of the drain electrode 142. A transparent conductive material, such as ITO, may be coated on the second insulation layer 146 and in the contact hole 148, through sputtering or evaporation, to form a conductive metal layer. Then, the conductive metal layer may be patterned using a mask, to form the pixel electrode 150 that is electrically connected to the drain electrode 142 through the contact hole 148.

Referring to FIG. 2I, the second photoresist pattern 151 is formed on the second insulation layer 146 in the non-display area. In particular, a photoresist material may be coated on the second insulation layer 146 and the pixel electrode 150 to form a second photoresist layer (not shown). Then, the second photoresist layer may be patterned using a mask, to form the second photoresist pattern 151.

The second photoresist pattern 151 may have a thickness of at least about four times that of the thickness of the subsequently second alignment layer 152. The second photoresist pattern 151 may be spaced apart from an edge of the display area, due to a process margin, by the second width W2.

Referring to FIG. 2J, the second alignment layer 152 is formed on the second photoresist pattern 151, the exposed second insulation layer 146, and the pixel electrode 150. The second alignment layer 152 may be formed by coating polyimide using roller coating, spin coating, or dipping. For example, the second alignment layer 152 may have a thickness of about 500 Å. The second alignment layer 152 may have a thinner thickness on a sidewall of the second photoresist pattern 151 than on a top surface of the second photoresist pattern 151 and the second insulation layer 146.

Referring to FIG. 2K, the second photoresist pattern 151 is removed through a lift-off process. The lift-off process may be performed using an etchant having a higher etching selectivity with respect to the second photoresist pattern 151 than with the second alignment layer 152. For example, sulfuric acid solution (H₂SO₄) having a temperature of about 150° C. to about 180° C. may be used as the etchant.

The portion of the second alignment layer 152 disposed on the sidewall of the second photoresist pattern 151 may be etched away during the lift-off process, so that an upper portion of the sidewall of the second photoresist pattern 151 is exposed. Then, the exposed second photoresist pattern 151 may be quickly etched, and thus, the portion of the second alignment layer 152 formed on the second photoresist pattern 151 may be removed. Thus, the second alignment layer 152 remains on only the second insulation layer 146 and the pixel electrode 150.

The second alignment layer 152 extends into the non-display area by the second width W2 of about 1 μm to about 99 μm. Therefore, the thin film transistor substrate 130 is formed.

Referring to FIG. 21, the seal pattern 160 is formed on the second insulation layer 146 in the non-display area. The seal pattern 160 is spaced apart from the second alignment layer 152. The seal pattern 160 may have a square frame shape having an opening (not shown) corresponding to one area of the first black matrix 112a. For example, the seal pattern 160 may have the third width W3 of about 0.2 mm to about 0.7 mm. For example, the seal pattern 160 may be spaced apart from at least one of the first alignment layer 120 and the second alignment layer 152 by a distance d of about 0.1 mm to about 0.5 mm.

The sealant may be coated on the exposed second insulation layer 146 and the second alignment layer 152. The coated sealant may be patterned using a mask, so as to form the seal pattern 160 on a portion the first black matrix 112a.

Referring to FIG. 2M, the color filter substrate 110 and the thin film transistor substrate 130 are bonded using the seal pattern 160. For example, the color filter substrate 110 may be aligned with the thin film transistor substrate 130, and then, heat or light may be irradiated onto the seal pattern 160. As a result, the color filter substrate 110 and the thin film transistor 130 may be bonded by the seal pattern 160. Here, the seal pattern 160 may be attached to the second insulation layer 146 and the first black matrix 112a.

Referring to FIG. 2N, the liquid crystal layer 170 is inserted between the color filter substrate 110 and the thin film transistor substrate 130, through an opening (not shown). The liquid crystal layer 170 may include the liquid crystals 172 having optical anisotropic characteristics. The opening may be sealed after the liquid crystal layer 170 is inserted, to complete the manufacture the liquid crystal display device 100.

According to various embodiments of the present inventive concept, portions of the first and second alignment layers 120 and 152 that are disposed in the non-display area may be reduced through the lift-off process, to prevent the seal pattern 160 and the first and second alignment layers 120 and 152 from overlapping each other. Thus, a liquid crystal display device manufacturing method, in which the first black matrix 112a may be stably formed, may be provided. Therefore, the upper and lower substrates 110 and 130 of the liquid crystal display device 100 are securely attached to one another, thereby preventing product defects.

Although the color filter substrate 110 is recited to be formed and then the thin film transistor substrate 130 is formed, the thin film transistor substrate 130 may be formed first, and then the color filter substrate 110 may be formed.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A liquid crystal display device comprising:
a first substrate and an opposing second substrate, the first substrate and the second substrate comprising a display area to display an image and a non-display area surrounding the display area;
a first black matrix disposed on the first substrate and in the non-display area;
a first insulation layer disposed on the second substrate and facing the first black matrix;
a first alignment layer disposed on the first substrate, in the display area, and extending onto a portion of the first black matrix;
a second alignment layer disposed on the second substrate, in the display area, and extending into the non-display area; and
a seal pattern disposed in the non-display area to connect the first and second substrates, the seal pattern being spaced apart from at least one of the first alignment layer and the second alignment layer.

2. The liquid crystal display device of claim 1, wherein the first and second alignment layers extend into the non-display area by a distance of 1 μm to 99 μm.

3. The liquid crystal display device of claim 1, wherein the first black matrix has a width of 0.3 mm to 1.2 mm, the width being measured from an edge of the display area toward and outer edge of the non-display area.

4. The liquid crystal display device of claim 1, further comprising:
a thin film transistor disposed on the second substrate and in the display area, the thin film transistor comprising a gate electrode, a semiconductor layer, a source electrode, and a drain electrode;
a gate insulation layer disposed on the second substrate, between the gate electrode and the semiconductor layer, the gate insulation layer extending from the display area into the non-display area;
a second insulation layer disposed between the thin film transistor and the first insulation layer and between an exposed surface of the gate insulation layer and the first insulation layer; and
a pixel electrode disposed between the first insulation layer and the second alignment layer in the display area and electrically connected to the drain electrode.

5. The liquid crystal display device of claim 1, further comprising:
color filter layers disposed on the first substrate and in the display area;
a second black matrix disposed on the first substrate and between the color filter layers; and
a common electrode disposed between the color filter layers and the first alignment layer, and between the second black matrix and the first alignment layer.

6. A method of manufacturing a liquid crystal display device comprising a display area and a non-display area, the method comprising:
forming a thin film transistor on a second substrate and in the display area, forming a first insulation layer on the thin film transistor, and forming a pixel electrode formed on the first insulation layer and connected to a drain electrode of the thin film transistor;
forming a second photoresist pattern on the first insulation layer and in the non-display area;
forming a second alignment layer on the second photoresist pattern, the pixel electrode, and the first insulation layer;
removing the second photoresist pattern and a portion of the second alignment layer disposed on the second photoresist pattern, using a lift-off process; and
forming a seal pattern that is spaced apart from the portion of the second alignment layer remaining on the first insulation layer.

7. The method of claim 6, further comprising:
forming a first black matrix on a first substrate and in the non-display area, and forming a second black matrix, a color filter layer, and a common electrode on the first substrate and in the display area,
wherein the color filter layer and the common electrode are formed on the second black matrix and an edge of the first black matrix;
forming a first photoresist pattern on the first black matrix;
forming a first alignment layer on the first photoresist pattern and the common electrode;
removing the first photoresist pattern and a portion of the first alignment layer formed on the first photoresist pattern, using a lift-off process; and bonding the first substrate and the second substrate using the seal pattern, such that the first black matrix contacts the first insulation layer.

8. The method of claim 7, wherein the lift-off process is performed using an etchant having a higher etching selectivity with respect to one of the first photoresist pattern and the second photoresist pattern than to one of the first alignment layer and the second alignment layer.

9. The method of claim 8, wherein at least one of the first alignment layer and the second alignment layer extends by 1 μm to 99 μm from an edge of the display area into the non-display area.
